(19) United States
(12) Patent Application Publication
(10) Pub. No.: US 2011/0061847 A1
(43) Pub. Date: Mar. 17, 2011

(54) HEAT DISSIPATION DEVICE

(76) Inventor: Meng-Hsiu Hsieh, Taichung (TW)

(21) Appl. No.: 12/558,264

(22) Filed: Sep. 11, 2009

(51) Int. Cl. H01L 23/34; F28F 7/00; H01L 23/367; H01L 23/40

(52) U.S. Cl. 165/185

(57) ABSTRACT

A heat dissipation apparatus includes a heat conductive plate, a heat-dissipating fin set and a fastener. The heat-dissipating fin set has a bottom surface attached to a top surface of the heat conductive plate. The fastener includes a curled section and two legs joined to opposite ends of the curled section. Basically, the curled section is elastically deformable and has a trough pressing against a top surface of the heat-dissipating fin set and a crest spaced apart from the top surface of the heat-dissipating fin set. Each of the legs of the fastener has a clasping member to be fastened on heat conductive plate. When the clasping members of the legs are fastened on the heat conductive plate, the curled section is tightened by the legs.

### BACKGROUND OF INVENTION

1. Field of Invention

This invention relates to a heat dissipation apparatus for dissipating heat generated by a chip, and more particularly to a heat dissipation apparatus which is made up of combination of a heat conductive plate and a heat-dissipating fin set.

2. Related Prior Art

A conventional approach to attaching a heat sink onto a chip has been to mount the whole heat sink on a carrier, which holds the chip, with the help of a fastener. A list of exemplary patents that describe some of these exemplary methods and apparatus are as follows: T.W. Pat. Nos. 286791, 311706, 571609, 437993 and M326763. Each of these patents discloses the usage of a wave-shaped fastener. However, none of the fasteners is used for fastening together a conductive plate and a heat-dissipating fin set to be a heat sink since the conductive plate and the heat-dissipating fin set are formed in one piece.

Another mechanism for heat dissipation apparatus is described in T.W. Pat. No. 501765 and includes a wave-shaped bar, a heat-dissipating fin set and a U-shaped holder. The wave-shaped bar, mounted across the U-shaped holder and the heat-dissipating fin set, is provided to prevent the heat-dissipating fin set from departing away from the U-shaped holder. Specifically, the wave-shaped bar is received in a through hole co-defined by the fins of the heat-dissipating fin set. It is understood that it must be quite difficult for the wave-shaped bar to be inserted into the through hole of the heat-dissipating fin set as well as the holes defined in the side walls of the U-shaped holder, which generally increases assembly complexity of the apparatus.

### SUMMARY OF INVENTION

Broadly stated, the present invention is directed to a heat dissipation apparatus for dissipating heat generated by a chip. The heat dissipation apparatus mainly includes a heat conductive plate, a heat-dissipating fin set and a fastener.

Specifically, the heat-dissipating fin set has a bottom surface attached to a top surface of the heat conductive plate. The fastener includes a curled section and two legs joined to opposite ends of the curled section. The curled section is elastically deformable and is mounted across the heat-dissipating fin set. In addition, the curled section has at least one trough pressing against a top surface of the heat-dissipating fin set and at least one crest spaced apart from the top surface of the heat-dissipating fin set. Each of the legs of the fastener has a clasping member to be fastened on the heat conductive plate. When the clasping members of the legs are fastened on the heat conductive plate, the curled section is tightened by the legs. In such a manner, the heat dissipating fin set can be quickly mounted on the heat conductive plate without the need of soldering.

In another embodiment, a lining plate is included to be placed in between the curled section of the fastener and the heat-dissipating fin set. The lining plate is provided to help dispersing the force from the curled section to the heat-dissipating fin set, which simultaneously creates a close contact therebetween.

The advantages of the present invention will be understood more readily after a consideration of the drawings and the detailed description.

### BRIEF DESCRIPTION OF DRAWINGS

The invention is illustrated by the accompanying drawings in which corresponding parts are identified by the same numerals and in which:

FIG. 1 is a perspective view of a heat dissipation apparatus according to one embodiment;

FIG. 2 is a lateral cross-sectional view of the heat dissipation of FIG. 1;

FIG. 3 is an exploded view of the heat dissipation of FIG. 1; and

FIG. 4 is a longitudinal cross-sectional view of the heat dissipation of FIG. 1.

### DETAILED DESCRIPTION OF EMBODIMENTS

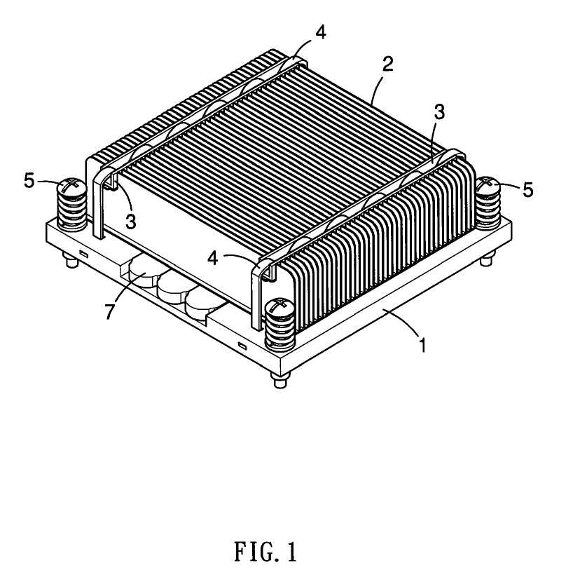

Referring now to FIGS. 1 through 4 of the drawings, this invention in accordance with one embodiment is directed to a heat dissipation apparatus for dissipating heat generated by a central processing unit (CPU).

As shown in FIG. 1, the heat dissipation apparatus includes a heat conductive plate 1, a heat-dissipating fin set 2 placed on the heat conductive plate 1, two liners 3 disposed on the heat-dissipating fin set 2, two fasteners 4 received in the two liners 3, and four fixing bolt units 5 secured at comers of the heat conductive plate 1. In particular, each of the fasteners 4 has opposite ends fastened on the heat conductive plate 1 in order to press against the heat-dissipating fin set 2.

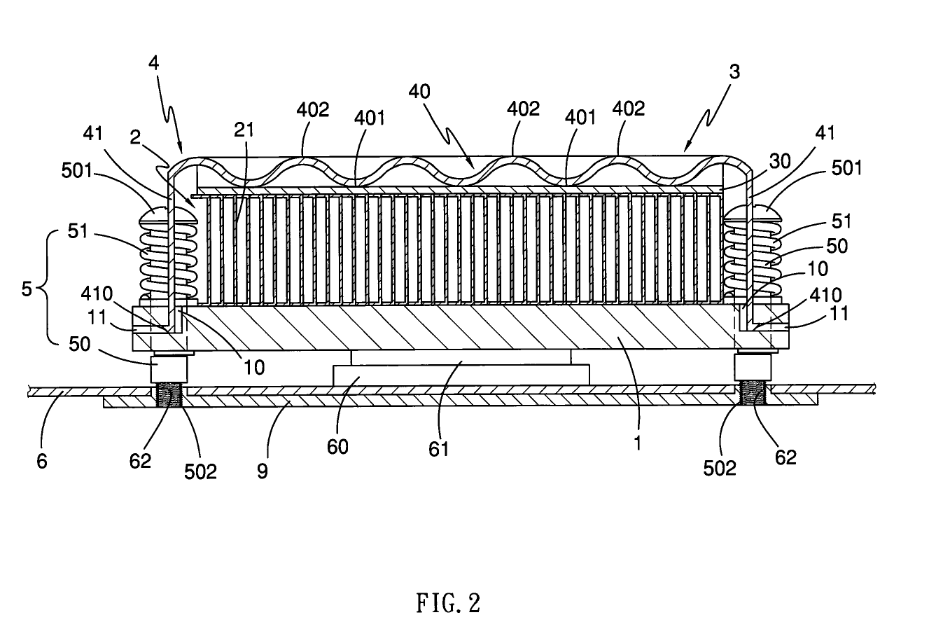

As shown in FIG. 2, the heat dissipation apparatus is adopted to be mounted on a printed circuit board 6, such as a computer motherboard, on which a chip carrier 60 is mounted. Upon the carrier 60 is a chip 61, such as CPU. Note that it is the four fixing bolt units 5 to be used to quick mount the heat dissipation apparatus on the printed circuit board 6 rather than the fasteners 4. Each of the fixing bolt units 5 includes a bolt 50 and a compression spring 51. The bolt 50 has one end formed with a head 501 and the other end formed with a threaded portion 502. The compression spring 51 is placed around the bolt 50 and between the head 501 of the bolt 50 and a top surface of the heat conductive plate 1. The threaded portion 502 of the bolt 50 is mounted across a threaded hole defined in the printed circuit board 6 and screwed on a frame 9. The heat conductive plate 1 has a bottom surface in close contact with the chip 61. The heat-dissipating fin set 2 has a bottom surface in close contact with the top surface of the heat conductive plate 1. Therefore, the heat generated within the chip 61 can be dissipated to the heat-dissipating fin set 2 via the heat conductive plate 1.

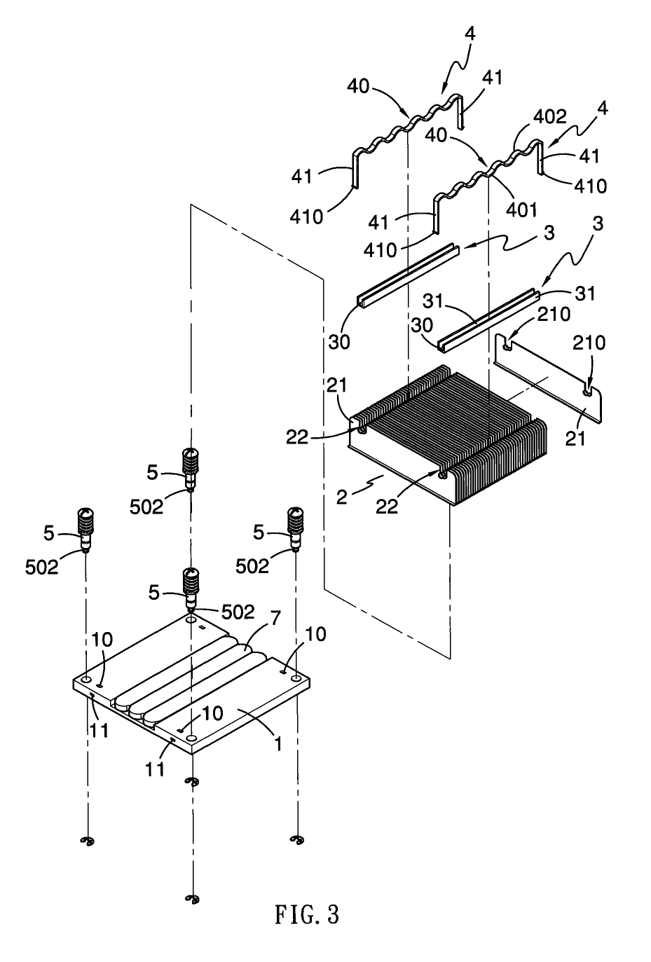

The heat conductive plate 1 may be made of a single heat conductive material, such as copper, aluminum, ceramics, or the like. Alternatively, the heat conductive plate 1 may be made of complex materials or multi-layer materials. To efficiently dissipate the heat, one or more heat pipes 7 are included to be sandwiched between the heat conductive plate 1 and the heat-dissipating fin set 2, as shown in FIGS. 1 and 3. In this case, the top surface of the heat conductive plate 1 is not complete flat but with an indentation therein to receive the heat pipes 7. In another case where a complete flat top surface of the heat conductive plate is desired, a notch may be defined in the bottom surface of the heat-dissipating fin set 2 rather than in the top surface of the heat conductive plate 1 to receive the heat pipes 7.

The heat-dissipating fin set 2 may be made in the aluminum extrusion process or made by punched metal sheets, for example: copper sheets or aluminum sheets. Preferably, the heat-dissipating fin set 2 is made up of a plurality of copper sheets or aluminum sheets. As shown in FIGS. 2 and 3, the heat-dissipating fin set 2 is composed of a plurality of heat-dissipation fins 21 parallel with one another. Each of the fins 21 has a bottom edge placed on the top surface of the heat conductive plate 1 and a top edge defining two concaves therein. The concaves 210 of the top edge of the fin 21 stand in a row to co-define a long, straight channel 22, as shown in FIG. 2. The two channels 22 are parallel to each other to receive the two liners 3. In other examples, different quantity of the concave(s) for each one of the fins 21 may be used to create one or more channels 22 for receiving one or more liners 3. The quantity of the liner(s) 3 depends on that of the fastener(s) 4 which may be one or more.

As shown in FIGS. 1 to 3, each of the fasteners 4 includes a curled section 40 and two legs 41 joined to opposite ends of the curled section 40. The curled section 40 is elastically deformable and has at least one troughs 401 pressing against a top surface of the heat-dissipating fin set 2 and at least one crests 402 spaced apart from the top surface of the heat-dissipating fin set 2. Each of the liners 3, preferably made of a conductive metal, includes a lining plate 30. The lining plate 30 is received in the channel 22 of the heat-dissipating fin set 2 and is pressed by the curled section 40 of the fastener 4. Specifically, the lining plate 30 has a flat bottom surface pressing against a bottom surface of the channel 22 and a flat top surface being pressed by the trough 401 of the curled section 40.

Referring to FIGS. 2 and 3, each of the two legs 41 of the fastener 4 has a clasping member 410 to be fastened on the heat conductive plate 1. Practically, each clasping member 410is a hook. The two fasteners 4 include four clasping members 410 in total. In order to receive the four clasping members 410, the heat conductive plate 1 defines four vertical holes 10 and four horizontal holes 11 therein. The four vertical holes 10 are defined in the top surface of the heat conductive plate 1 and located at comers of the same. As for the four horizontal holes 11, two are defined in one side surface of the heat conductive plate 1 while the other two are defined in the opposite side surface of the heat conductive plate 1. As shown in FIG. 2, the four horizontal holes 10 are in vertical communication with the four vertical holes 11 respectively. The clasping members 410, namely the hooks, are able to be inserted into the respective vertical holes 11 and then hooked in the respective horizontal holes 10. In such a manner, each of the fasteners 4 can be easily, quickly and securely fastened on the heat conductive plate 1 because the clasping members 410 are safely hidden in the respective vertical and horizontal holes 10 and 11 from being touched or loosen by others. On the contrary, each one of the clasping members 410 can be pushed inward by insertion of an insert into the horizontal hole 11 so as to allow the leg 41 together with its clasping member 410 to be removed from the horizontal holes 10, and therefore to dismantle the fastener 4.

As can be seen in FIG. 2, the clasping members 410 of the legs 41 of the fasteners 4 are fastened on the heat conductive plate 1. At this time, each curled section 40 is tighten by the opposite legs 41 such that the troughs 401 of the curled section 40 of the fastener 4 can tightly press against the lining plate 30. Therefore, the heat-dissipating fin set 2 can be tightly pressed against the heat conductive plate 1 and secured on heat conductive plate 1 as a result of the fasteners 4. Further, since the heat-dissipating fin set 2 and the heat conductive plate 1 are tightly bonded together, the heat transfer therebetween is greatly enhanced. No soldering is needed to connect the heat-dissipating fin set 2 and the heat conductive plate 1, and therefore the manufacturing process is simplified and the cost are relatively reduced. Nevertheless, it is suggested to employ a thermal grease or thermal paste to be coated in between the heat-dissipating fin set 2 and the heat conductive plate 1 in order to further enhance the heat transfer.

The fasteners 4 are made of elastic metals. Preferably, the material of the fasteners 4 is relatively hard-to-deform by heat when compared with the heat-dissipating fin set 2, for example: stainless, iron, copper, etc. As such, the heat-induced expansion between the heat-dissipating fin set 2 and the heat conductive plate 1 will further lead the trough 401 of the curled section 40 of the fastener 4 to tightly press against the heat-dissipating fin set 2, and therefore enhance the heat dissipation efficiency.

The lining plate 30 of the liner 3 placed in between the curled section 40 of the fastener 4 and the heat-dissipating fin set 2 helps to laterally disperse the force executed by the curled section 40 to a larger area instead of a certain points. Thus, the heat-dissipating fin set 2 is indirectly, evenly pressed by the curled section 40, which leads to a closer contact between the bottom surface of the heat-dissipating fin set 2 and the top surface of the heat conductive plate 1.

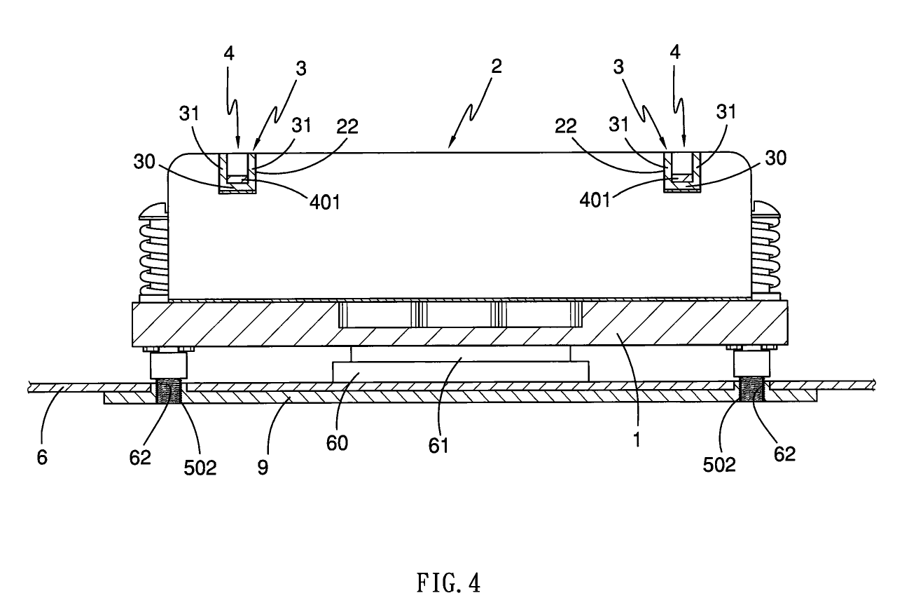

As shown in FIGS. 3 and 4, to avoid lateral displacement of the fasteners 4, each of the liners 3 further includes two side plates 31 standing upright at two opposite edges of the top surface of the lining plate 30. The exterior surfaces of the two side plates 31 of the liner 3 abut against opposite side surfaces of the channel 22 of the heat-dissipating fin set 2. The interior surfaces of the two side plates 3 1abut against opposite side edges of the curled section 40 of the fastener 4.

In another embodiment, the channel 22 defined in the heat-dissipating fin set 2 is omitted, when compared with the aforementioned embodiment. That is, the top surface of the heat-dissipating fin set 2 is complete flat. The cured section 40 of the fastener 4 directly presses on the flat top surface of the heat-dissipating fin set 2. In the case where the top surface of the heat-dissipating fin set 2 is not flat enough, a lining plate 30 may be introduced in between the fastener 4 and the heat-dissipating fin set 2 to provide a better contact therebetween. Specifically, the lining plate 30 has a flat bottom surface pressing against the top surface of the heat-dissipating fin set 2 and a flat top surface being pressed by the trough 401 of the fastener 4.

In yet another embodiment, the liner 3 is omitted, when compared with the first aforementioned embodiment. That is, the curled section 40 of the fastener 4 directly presses on the bottom surface of the channel 22 of the heat-dissipating fin set 2. The opposite side surfaces of the channel 22 of the heat-dissipating fin set 2 abut against the opposite side edges of the curled section 40 of the fastener 4. Preferably, the bottom surface of the channel 22 is quite even so that the curled section 40 can evenly press toward the heat-dissipating fin set 2.

It will be appreciated that although a particular embodiment of the invention has been shown and described, modifications may be made. It is intended in the claims to cover such modifications which come within the spirit and scope of the invention.

The invention claimed is:

1. A heat dissipation apparatus comprising:
a heat conductive plate;
a heat-dissipating fin set having a bottom surface attached to a top surface of the heat conductive plate; and
a fastener including a curled section and two legs joined to opposite ends of the curled section; the curled section being elastically deformable and having at least one trough pressing against a top surface of the heat-dissipating fin set and at least one crest spaced apart from the top surface of the heat-dissipating fin set; the legs each having a clasping member to be fastened on heat conductive plate, wherein when the clasping members of the legs are fastened on the heat conductive plate, the curled section is tightened by the legs.

2. The heat dissipation apparatus of claim 1, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the clasping members of the legs are able to be inserted into the respective vertical holes and hooked in the respective horizontal holes.

3. A heat dissipation apparatus comprising:
a heat conductive plate;
a heat-dissipating fin set having a top surface and a bottom surface attached to a top surface of the heat conductive plate;
a fastener including a curled section and two legs joined to opposite ends of the curled section; the curled section being elastically deformable and having at least one trough pressing against the top surface of the heat-dissipating fin set, and at least one crest spaced apart from the top surface of the heat-dissipating fin set; the legs each having a clasping member to be fastened on heat conductive plate, wherein when the clasping members of the legs are fastened on the heat conductive plate, the curled section is tightened by the legs; and
a lining plate having a flat bottom surface pressing against the top surface of the heat-dissipating fin set and a flat top surface being pressed by the trough of the fastener.

4. The heat dissipation apparatus of claim 3, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and
the clasping members of the legs are able to be inserted into the two vertical holes and hooked in the respective horizontal holes.

5. A heat dissipation apparatus comprising:
a heat conductive plate having a top surface;
a heat-dissipating fin set including a plurality of fins; each of the fins having a bottom edge placed on the top surface of the heat conductive plate and a top edge defining a concave therein; wherein the concaves of the top edges of the fins are arranged in a row to co-define a channel; and
a fastener including a curled section and two legs joined to opposite ends of the curled section; the curled section being elastically deformable and having at least one trough pressing against a bottom surface of the channel of the heat-dissipating fin set, and at least one crest spaced apart from the bottom surface of the channel of the heat-dissipating fin set; and the legs each having a clasping member to be fastened on heat conductive plate, wherein when the clasping members of the legs are fastened on the heat conductive plate, the curled section is tightened by the legs.

6. The heat dissipation apparatus of claim 5, wherein the curled section of the fastener has opposite side surfaces abut against opposite side surfaces of the channel of the heat-dissipating fin set.

7. The heat dissipation apparatus of claim 5 further comprising a liner, wherein the liner includes a lining plate; and the lining plate has a flat bottom surface pressing against a bottom surface of the channel of the heat-dissipating fin set and a flat top surface being pressed by the trough of the fastener.

8. The heat dissipation apparatus of claim 7, wherein the liner further includes two side plates standing upright at two opposite edges of the top surface of the lining plate; and the two side plates of the liner have exterior surfaces abutting against opposite side surfaces of the channel of the heat-dissipating fin set and interior surfaces abutting against opposite side edges of the curled section of the fastener.

9. The heat dissipation apparatus of claim 5, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the two hooks is able to be inserted into the two vertical holes and hooked in the respective horizontal holes.

9. The heat dissipation apparatus of claim 5, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the two hooks is able to be inserted into the two vertical holes and hooked in the respective horizontal holes.

10. The heat dissipation apparatus of claim 6, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the two hooks is able to be inserted into the two vertical holes and hooked in the respective horizontal holes.

11. The heat dissipation apparatus of claim 7, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the two hooks is able to be inserted into the two vertical holes and hooked in the respective horizontal holes.

12. The heat dissipation apparatus of claim 8, wherein the clasping members of the legs of the fastener are hooks; the heat conductive plate has two vertical holes defined in the top surface thereof and two horizontal holes defined in opposite side surfaces thereof; one of the horizontal holes is in vertical communication with one of the vertical holes while the other horizontal hole is in vertical communication with the other vertical hole; and the two hooks is able to be inserted into the two vertical holes and hooked in the respective horizontal holes.
